(19) United States
(12) Patent Application Publication
(10) Pub. No.: US 2026/0246833 A1
(43) Pub. Date: Aug. 20, 2026

(54) ERASURE-CODED DATA TRANSFER USING REMOTE DIRECT MEMORY ACCESS (RDMA)

(71) Applicant: Microsoft Technology Licensing, LLC, REDMOND, WA (US)

(72) Inventors: Konstantin TARANOV, Zurich (CH); Joyce Ji-suk YOM, Kirkland, WA (US); Zhuolong YU, Kirkland, WA (US); Abdul KABBANI, Menlo Park, CA (US); Jitendra Dattatraya PADHYE, Redmond, WA (US); Mahmoud ELHADDAD, Newcastle, WA (US)

(21) Appl. No.: 19/054,413

(22) Filed: Feb. 14, 2025

(51) Int. Cl. H04L 67/1097; H03M 13/37

(52) U.S. Cl. CPC H04L 67/1097; H03M 13/373

(57) ABSTRACT

Methods, apparatuses, and products for erasure-coded data transfer using remote direct memory access (RDMA), including: partitioning, by a sender endpoint, a message to be sent to a receiver endpoint into a plurality of data segments by logically subdividing the message into a number of data segments defined as a parameter of an error coding scheme; generating, by the sender endpoint, one or more parity segments from the plurality of data segments by applying the error coding scheme to the plurality of data segments; and sending, by the sender endpoint and to the receiver endpoint, via a plurality of network connections, the plurality of data segments and the one or more parity segments using remote direct memory access (RDMA), wherein each of the data segments and each of the parity segments are sent using RDMA via different network connections of the plurality of network connections.

### BACKGROUND

Remote direct memory access (RDMA) enables data transfer directly to and from the buffers of a sender and recipient over a network. Because RDMA data transfer occurs at the memory level, other software and networking layers generally involved in network data transfer are not used. This provides for significant throughput increases while lowering latency relative to other data transmission approaches using software and networking layers. However, RDMA still relies on encoding and sending data in packets over one or more network connections.

When sending data packets over a network, it is possible for some of these packets to be lost during transfer. For example, network congestion occurs when switches or other network components become overburdened, which may lead to packet loss. To address this, a recipient of these data packets may request that the sender retransmit the missing packets to complete the data transfer.

Although retransmitting missing packets may allow the data transfer to complete, these implementations include several drawbacks. For example, a recipient requesting missing packets from a sender adds additional round-trips to the overall data transfer. Moreover, in some implementations, requesting a missing packet may require that all packets sent after the missing packet to also be resent, resulting in additional bandwidth and computational resource utilization as well as being inefficient due to retransmitting packets that may have already been successfully received.

### SUMMARY

According to embodiments of the present disclosure, various methods, apparatus, and products for erasure-coded data transfer using remote direct memory access (RDMA) are described herein. In some aspects, erasure-coded data transfer using remote direct memory access (RDMA) includes: partitioning, by a sender endpoint, a message to be sent to a receiver endpoint into a plurality of data segments by logically subdividing the message into a number of data segments defined as a parameter of an error coding scheme; generating, by the sender endpoint, one or more parity segments from the plurality of data segments by applying the error coding scheme to the plurality of data segments; and sending, by the sender endpoint and to the receiver endpoint, via a plurality of network connections, the plurality of data segments and the one or more parity segments using remote direct memory access (RDMA), wherein each of the data segments and each of the parity segments are sent using RDMA via different network connections of the plurality of network connections. In some aspects, an apparatus may include a memory and one or more processing devices, operatively coupled to the memory, the one or more processing devices configured to perform similar steps. In some aspects, a computer program product comprising a computer readable storage medium may store computer program instructions that, when executed, perform similar steps.

### BRIEF DESCRIPTION OF DRAWINGS

FIG. 1 sets forth a diagram of an example system for erasure-coded data transfer using

RDMA in accordance with some embodiments of the present disclosure.

FIG. 2 sets forth a flow chart illustrating an example method of erasure-coded data transfer using RDMA in accordance with some embodiments of the present disclosure.

FIG. 3 sets forth a flow chart illustrating an additional example method of erasure-coded data transfer using RDMA in accordance with some embodiments of the present disclosure.

FIG. 4 sets forth a flow chart illustrating an additional example method of erasure-coded data transfer using RDMA in accordance with some embodiments of the present disclosure.

FIG. 5 sets forth a flow chart illustrating an additional example method of erasure-coded data transfer using RDMA in accordance with some embodiments of the present disclosure.

FIG. 6 sets forth a flow chart illustrating an additional example method of erasure-coded data transfer using RDMA in accordance with some embodiments of the present disclosure.

FIG. 7 sets forth a flow chart illustrating an additional example method of erasure-coded data transfer using RDMA in accordance with some embodiments of the present disclosure.

FIG. 8 sets forth a flow chart illustrating an additional example method of erasure-coded data transfer using RDMA in accordance with some embodiments of the present disclosure.

FIG. 9 illustrates an exemplary computing device that may be specifically configured to perform one or more of the processes described in the present disclosure.

FIG. 10 sets forth a block diagram of a cloud service provider service architecture in accordance with some embodiments of the present disclosure.

### DESCRIPTION OF EMBODIMENTS

When sending data over a network, the data may be divided into multiple data packets by a sender. These multiple packets may be sent over the network to a recipient, potentially using multiple, different network paths to the recipient. This involves routing the data packets through multiple intermediary components between the sender and the recipient. Should any of these components be overburdened due to network congestion, it may be possible for some of these data packets to be dropped, never arriving at the recipient.

The recipient of the data packets may identify any lost data packets and request, from the sender, that they be resent. Though retransmitting lost packets may prevent overall failure of the data transfer, the retransmission process is time and resource intensive. In the event of a lost packet, an additional round trip of data between the recipient and the sender is required so that the recipient can request missing packets from the sender and receive those missing packets in response. Moreover, in some implementations, a lost packet may require that both the lost packet and any packets sent after that lost packet be retransmitted by the sender. This further adds to the time and resource usage required to complete the data transfer and is inefficient as it may include retransmitting packets that were already successfully received by the recipient.

To address these shortcomings, the approaches set forth herein allow for erasure-coded data transfer using RDMA. A message to be sent from a sender to a receiver is divided into multiple segments. These segments are used to generate parity segments, data storing parity information that enable reconstruction of missing data segments. The data segments and the parity segments are sent to the receiver using RDMA. Should the receiver fail to receive a data segment (e.g., due to packet loss) the missing data segment may be reconstructed using the received data segments and any received parity segments. Thus, the missing data segments can be recovered through reconstruction rather than through requesting that the missing data be retransmitted by the sender. Moreover, these approaches may be implemented using existing RDMA protocols such as InfiniBand, which use resource-efficient zero-copy send and receive operations that do not require creation of multiple copies of some data to be sent or that is received. In contrast to traditional data exchanges where data can be copied multiple times (e.g., copied from user space to kernel space, copied from kernel space to a device buffer), zero-copy data transfers circumvent unnecessary copying of data and instead can leverage mechanisms like memory mapping, direct memory access (DMA), or other mechanisms to allow direct access to data rather than leveraging multiple copies of data.

Mitigating data loss during transfer is essential in preventing negative consequences for a user, including performance degradation, data corruption, or unexpected errors. Though existing implementations may recover lost packets through retransmission, this process is time and resource intensive. The approaches set forth herein provide an approach for lost data recovery using reconstruction rather than retransmission. This improves the overall user experience by minimizing negative consequences associated with data loss while providing performance and resource usage improvements over existing solutions relying on retransmission.

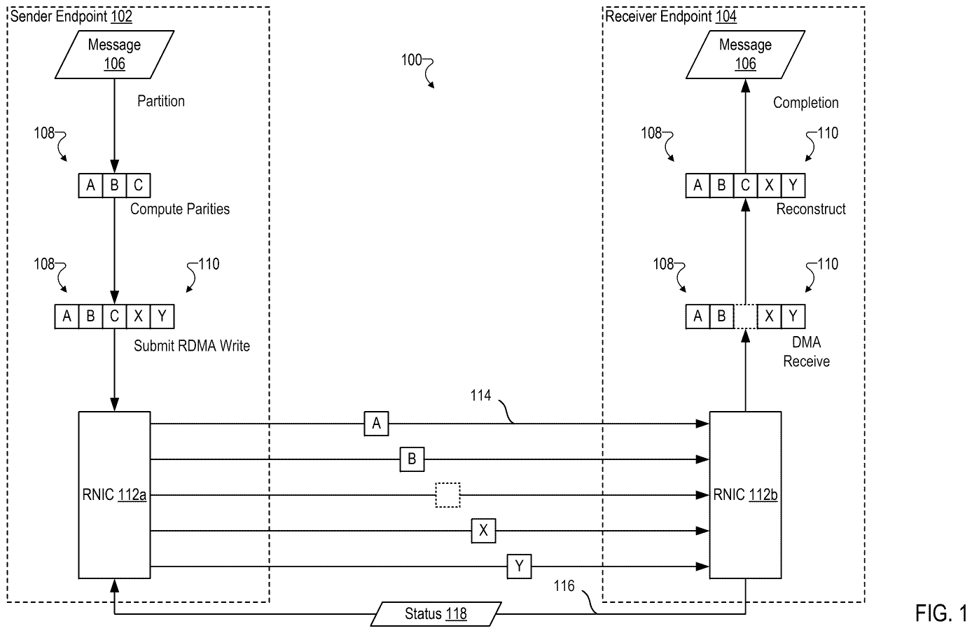

FIG. 1 sets forth an example system 100 for erasure-coded data transfer using RDMA in accordance with some embodiments of the present disclosure. The system 100 of FIG. 1 includes a sender endpoint 102 and a receiver endpoint 104. The sender endpoint 102 is a source of data, shown as a message 106, to be sent to the receiver endpoint 104. The sender endpoint 102 and receiver endpoint 104 may each include, for example, physical or virtual computing devices or other computing resources as can be appreciated. The message 106 may include any data to be sent from the sender endpoint 102 to the receiver endpoint 104. In some embodiments, the receiver endpoint 104 may send, to the sender endpoint 102, a receive request that includes a memory address of a buffer on the receiver endpoint 104 into which data can be written by the sender endpoint 102 using remote direct memory access (RDMA). In some embodiments, this buffer may be bound to a memory window that allows an application on the receiver endpoint 104 to control access to the buffer. In some embodiments, this receive request may include a token that can be used by the sender endpoint 102 as an authentication credential in performing RDMA write operations to this buffer. As the message 106 will be sent using erasure coding (EC), this receive request from the receiver endpoint 104 is hereinafter referred to as an EC_RECEIVE request. In some embodiments, each EC_RECEIVE request to a particular sender endpoint 102 may be sequentially numbered.

In some embodiments, an application executed on the sender endpoint 102 may generate a request to send the message 106 to the receiver endpoint 104, hereinafter referred to as an EC_SEND request. In some embodiments, the EC_SEND request may also include a sequential numbering. The sender endpoint 102 then determines if an EC_RECEIVE request with a matching sequential numbering has been received. The buffer description (e.g., the memory address and token) of this matching EC_RECEIVE request will be used in performing RDMA write operations to complete the EC_SEND request. In some embodiments, the use of sequentially numbered EC_SEND and EC_RECEIVE request guarantees in-order work request matching between the sender endpoint 102 and receiver endpoint 104, meaning that data from the Nth EC_SEND request will be written to the buffer provided with the Nth EC_RECEIVE request, even in the presence of packet drops.

Once the matching EC_RECEIVE request has been received, the sender endpoint 102 then partitions the message 106 into multiple data segments 108. Each data segment 108 is a logical subdivision of the message 106. In this example, the message 106 is partitioned into data segments 108 A, B, and C. This may include, for example, partitioning the message 106 in a send buffer into which the message 106, and therefore, the data segments 108, are stored. The particular number of data segments 108 into which a message 106 is partitioned may be determined using a variety of approaches. These approaches may vary according to design or engineering considerations.

In some embodiments, sender endpoint 102 partitions the message 106 into a predefined number of data segments 108. In some embodiments, sender endpoint 102 partitions the message 106 into a number of data segments 108 dependent on the size of the message 106. For example, the message 106 can be partitioned into data segments 108 of a predefined size. In some embodiments, sender endpoint 102 partitions the message 106 into a number of data segments 108 dependent on a number of network connections that may be used in sending the data segments 108 and parity segments 110, to be described in further detail below, to the receiver endpoint 104. For example, in some embodiments, the network connections between the sender endpoint 102 and receiver endpoint 104 are established prior to any particular EC_SEND or EC_RECEIVE requests being generated as part of a synchronization operation between the sender endpoint 102 and receiver endpoint 104 endpoint. This may include establishing a predefined number of network connections for data segments 108 and parity segments 110, respectively (e.g., for a predefined number of data segments 108 and parity segments 110 to be generated for a given message 106).

The sender endpoint 102 then generates, from the data segments 108, one or more parity segments 110 using an EC algorithm. These parity segments 110 may also be stored in the send buffer described above. The EC algorithm may include, for example, a Reed-Solomon EC scheme or another EC algorithm as can be appreciated. Each parity segment 110 is data generated from the data segments 108 that may be used in reconstructing lost data segments 108. In some embodiments, the number of parity segments 110 generated affects the maximum number of segments (e.g., for both data segments 108 and parity segments 110) that may be lost without losing the ability to reconstruct missing data segments 108. For example, assuming a Reed-Solomon scheme of RS(K, M) used by the sender endpoint 102 to generate M parity segments 110 from K data segments 108, up to M total data segments 108 and parity segments 110 may be lost while maintaining the ability to reconstruct the missing data segments 108. In this example, two parity segments 110 X and Y are generated. Readers will appreciate that the particular number of parity segments 110 to be generated may vary according to design or engineering considerations, including the various approaches described above for determining a number of data segments 108 into which a message 106 is partitioned.

The sender endpoint 102 then submits RDMA write operations to a RDMA Network Interface Controller (RNIC) 112a to send the data segments 108 and parity segments 110 to the receiver endpoint 104. In some embodiments, these RDMA write operations include RDMA Write with Immediate Unreliable Connected (UC) work requests as included in the InfiniBand specification. RDMA Write with Immediate UC work requests are write operations that use RDMA Queue Pairs (QPs), described in further detail below, that do not guarantee reliable delivery of data. Particularly, UC QPs can withstand packet drops and do not perform retransmissions, allowing for control of drop recovery by libraries or applications performing the data transfer.

Each data segment 108 and parity segment 110 may be sent using its own corresponding

RDMA write operation. Each RDMA write operation may include a memory address of the receiver endpoint 104 (e.g., a memory address included in the buffer indicated in the corresponding EC_RECEIVE request) and the token included in the corresponding EC_RECEIVE request. Each RDMA write operation may also include a memory address indicating where the corresponding data segment 108 and parity segment 110 are stored, such as in the send buffer described above. This allows the data segments 108 and parity segments 110 to be written to the receiver endpoint 104 using zero-copy communication (e.g., using zero-copy write operations). In a zero-copy write operation, the RNIC 112a accesses the data to be sent directly using a memory address pointer indicating where the data is stored, allowing the data to be sent without making additional copies. This is in contrast to other data transmission approaches whereby the data to be sent is copied into the kernel, and potentially copied further, before a frame is sent to a network controller. Thus, overall storage usage and performance is improved.

Each data segment 110 and parity segment 110 is sent from the RNIC 112a to another RNIC 112b on the receiver endpoint 104 using RDMA write operations over different network connections 114. In some embodiments, each network connection 114 includes a network connection between a QP of the sender endpoint 102 and a QP of the receiver endpoint 104. A QP is an addressable entity under the InfiniBand specification that represents a pair of queues, a send queue used for sending data and a receive queue for receiving data. Thus, in order to send K data segments 108 and M parity segments 110 using RS(K, M) erasure coding, both the sender endpoint 102 and the receiver endpoint 104 each create K+M QPs. Network connections 114 are established between each QP on the sender endpoint 102 and each corresponding QP on the receiver endpoint 104.

In some embodiments, the sender endpoint 102 and the receiver endpoint 104 establish an additional management network connection 116 for exchanging management messages, requests, or other data as can be appreciated. For example, the management network connection 116 may be used by the receiver endpoint 104 to send the EC_RECEIVE request to the sender endpoint 102. As another example, to be described in further detail below, the management network connection 116 may be used to exchange status 118 messages. In some embodiments, the management network connection 116 may include another connection between QPs or another type of network connection as can be appreciated.

In some embodiments, each network connection 114 may correspond to a different network path between the sender endpoint 102 and the receiver endpoint 104 such that the data segments 108 and parity segments 110 are each sent using different network paths. For example, in some embodiments, packets encoding the data segments 108 and parity segments 110 are be routed using hash-based routing. In hash-based routing, a hash value is calculated for a given packet using header fields of that packet. The packet is then routed to the next point based on the hash value. Thus, packets having the same hash value will be routed along the same network path. Accordingly, in some embodiments, packets for a given data segment 108 or parity segment 110 are be encoded with the same set of header fields used in calculating the hash value such that each packet for the same data segment 108 or parity segment 110 is sent using the same network path. For example, in some embodiments, an entropy value (EV) of a packet header such as a User Datagram Protocol (UDP) source port is used in calculating a hash value for hash-based routing. The sender endpoint 102 then sets the EV for each packet of the same data segment 108 or parity segment 110 to a particular value, with this EV differing for each data segment 108 and parity segment 110.

The receiver endpoint 104 then writes any received data segments 108 and parity segments 110 to the receive buffer described above (e.g., as indicated in their respective RDMA write operations). This may include the receiver endpoint 104 receiving data segments 108 and parity segments 110 using zero-copy receive operations whereby the RNIC 112b writes received data directly to the buffer without duplicating the received data segments 108 and parity segments 110 in memory of the receiver endpoint 104. In some embodiments, for each successfully received data segment 108 or parity segment 110, the RNIC 112b or an API used in performing the RDMA data transfer generates a completion event that includes a value (e.g., a thirty-two-bit value or another value) encoding the sequential number of the EC_SEND and EC_RECEIVE request and an identifier of the corresponding network path from which the segment was received. This completion event may be visible to a library supporting the operations described herein but not to higher level applications.

In this example, the data segment 108 C has been lost during transfer. This may be due to one or more packets encoding the data segment 108 C being lost during transfer. In some embodiments, the receiver endpoint 104 applies one or more rules to determine whether a segment (e.g., a data segment 108 or parity segment 110) has been lost. This may include, for example, waiting a threshold amount of time to receive the segment before the segment is deemed lost. This threshold amount of time may begin from various events, such as a time since data was last received via the network connection 114 corresponding to the potentially lost segment, a time since transfer of some other segment was completed, a time since data for some segment was first received, or other events as can be appreciated. Once the threshold amount of time has been reached, the segment may be deemed lost.

Accordingly, the receiver endpoint 104 reconstructs the data segment 108 C using the other received data segments 108 and parity segments 110. In some embodiments, reconstructing the data segment 108 C may include restricting access of the sender endpoint 102 to memory into which the data segment 108 C was to be stored (e.g., in the receive buffer). This may include using a Memory Window Invalidate request. Restricting access to this memory prevents data from being written by the sender endpoint 102 during the reconstruction process. After reconstructing the data segment 108 C, all data segments 108 of the message 106 have been received, completing the message 106 transfer. As the receiver endpoint 104 was able to reconstruct the missing data segment 108 C, the receiver endpoint 104 sends, via the management network connection 116, a data transfer completeness status (e.g., a status 118) indicating a successful data transfer. In some embodiments, a signal may be generated (e.g., to an application or process on the receiver endpoint 104) indicating successful completion of the data transfer. In some embodiments, a signal may be generated (e.g., by a library implementing the approaches set forth herein) in the sender endpoint 102 reflecting the received status 118. This signal may then be received by a higher-level application that initiated the data transfer using this library.

In this example, the receiver endpoint 104 was able to reconstruct the lost data segment 108 C as only a single data segment 108 was lost, less than the maximum of two lost segments supported by the two parity segments 110. Instead, consider another example where the data segments 108 A and C, as well as parity segment 110 Y, were lost. In other words, only data segment 108 B and parity segment 110 X were received. In this other example, the missing data segments 108, and therefore the message 106, cannot be reconstructed as three segments were lost but only two parity segments 110 were used. Accordingly, the receiver endpoint 104 may send, to the sender endpoint 102, a data transfer completeness status (e.g., a status 118) indicating a failed data transfer. In some embodiments, this status 118 may indicate which segments were not received.

In response to receiving this status 118, a signal may be generated in the sender endpoint 102 reflecting the received status 118. This may allow a higher-level application receiving this signal to determine how to handle the lost segments. For example, in some embodiments, the sender endpoint 102 may reattempt transfer of the lost segments. As another example, in some embodiments where partial data transfer is acceptable, the sender endpoint 102 may determine to not reattempt transfer of the lost segments.

Readers will appreciate that the approaches set forth above allow for error-coded data transfer using RDMA. Where some data is lost during transfer, the lost data may be reconstructed using received parity data. This allows for the data transfer to be completed in a single round trip even in the event of data loss. This is in contrast to other implementations whereby retransmission of lost data is requested by the receiver from the sender, adding in additional round trip times to the data transfer. Thus, overall performance and resource utilization is improved. Moreover, these approaches may leverage existing RDMA standards or implementations such as InfiniBand, reducing the overall implementation complexity, resource usage, and cost.

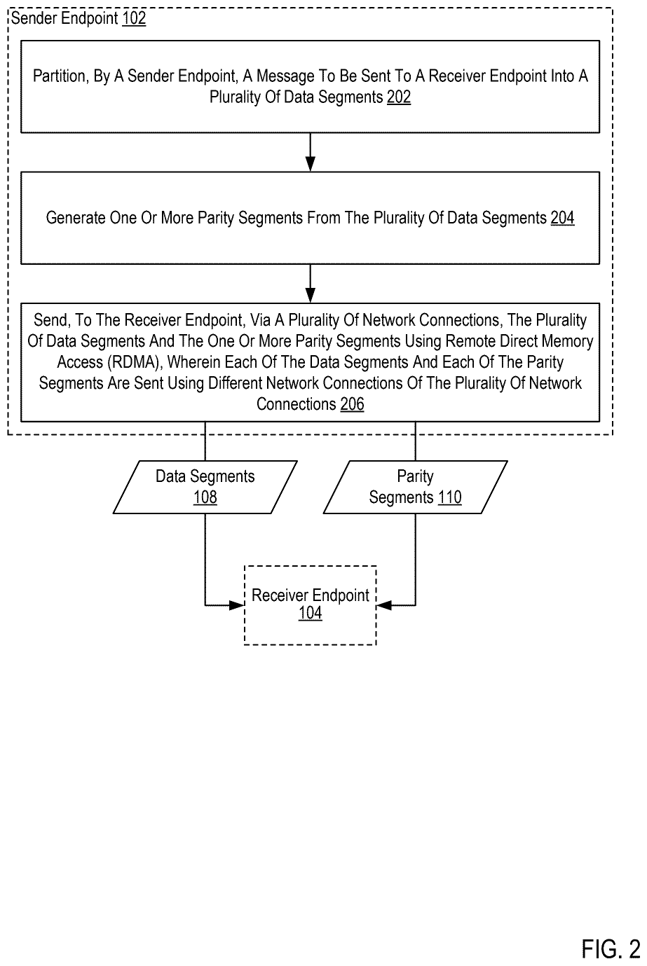

For further explanation, FIG. 2 sets forth a flowchart of an example method of erasure-coded data transfer using RDMA in accordance with some embodiments of the present disclosure. The method of FIG. 2 may be performed, for example, by a system 100 of FIG. 1. The method of FIG. 2 includes: partitioning 202, by a sender endpoint 102, a message 106 to be sent to a receiver endpoint 104 into a plurality of data segments 108. Each data segment 108 is a logical subdivision of the message 106. In some embodiments, partitioning 202 the message 106 into the plurality of data segments 108 includes the sender endpoint 102 partitioning the message 106 in a send buffer into which the message 106, and therefore, the data segments 108, are stored.

The method of FIG. 2 also includes generating 204 (e.g., by the sender endpoint 102) one or more parity segments 110 from the plurality of data segments 108. Each parity segment 110 is data generated from the data segments 108 that may be used in reconstructing lost data segments 108. The one or more parity segments 110 may be generated from the data segments 108 using an EC algorithm such as Reed-Solomon or another EC algorithm as can be appreciated. These parity segments 110 may also be stored in the send buffer described above. In some embodiments, the number of parity segments 110 generated determines the maximum number of segments that may be lost without losing the ability to reconstruct missing data segments 108. For example, assuming a Reed-Solomon scheme of RS(K, M) that generates M parity segments 110 from K data segments 108, up to M total data segments 108 and parity segments 110 may be lost while maintaining the ability to reconstruct the missing data segments 108. In other words, missing data segments 108 may be reconstructed by the receiver endpoint 104 provided that the number of missing data segments 108 is less than or equal to the number of received parity segments 110.

The method of FIG. 2 also includes sending 206, to the receiver endpoint 104, via a plurality of network connections 114, the plurality of data segments 108 and the one or more parity segments 110 using RDMA, wherein each of the data segments 108 and each of the parity segments 110 are sent using different network connections 114 of the plurality of network connections 114. Thus, to send K data segments 108 and M parity segments 110, K+M network connections 114 are used. In some embodiments, each network connection 114 may include a connection between a QP on the sender endpoint 102 and a corresponding QP on the receiver endpoint 104.

In some embodiments, each data segment 108 and parity segment 110 is sent using its own corresponding RDMA write operation. In some embodiments, these RDMA write operations may include RDMA Write with Immediate UC work requests as included in the InfiniBand specification. In some embodiments, sending 206 the plurality of data segments 108 and the one or more parity segments 110 may include submitting RDMA write operations to a network interface configured to perform RDMA operations, such as an RNIC 112a. Each RDMA write operation may include a memory address of the receiver endpoint 104 into which the corresponding data will be written. In some embodiments, each RDMA write operation may include a token that serves as an authentication credential for the sender endpoint 102. In other words, the token grants permission for the sender endpoint 102 to write data to an area of memory corresponding to the token.

For example, in some embodiments, prior to sending 206 the plurality of data segments 108 and the one or more parity segments 110, the receiver endpoint 104 sends a request such as an EC_RECEIVE request indicating a memory address of an area of memory into which data may be written and a token that grants the sender endpoint 102 permissions to write data to that area using RDMA. Each RDMA write operation may also include a memory address indicating where the corresponding data segment 108 and parity segment 110 are stored, such as in the send buffer described above.

In some embodiments, each network connection 114 corresponds to a different network path between the sender endpoint 102 and the receiver endpoint 104 such that each data segment 108 and parity segment 110 is sent using different network paths. For example, in some embodiments, sending 206 the plurality of data segments 108 and the one or more parity segments 110 includes encoding, into each packet for the same data segment 108 or parity segment 110, a particular EV. Thus, packets for the same data segment 108 or parity segment 110 may share the same EV while packets for different data segments 108 or parity segments 110 will have different EVs. The EV may include a packet header field used to calculate a hash value for hash-based routing, such as a UDP source port.

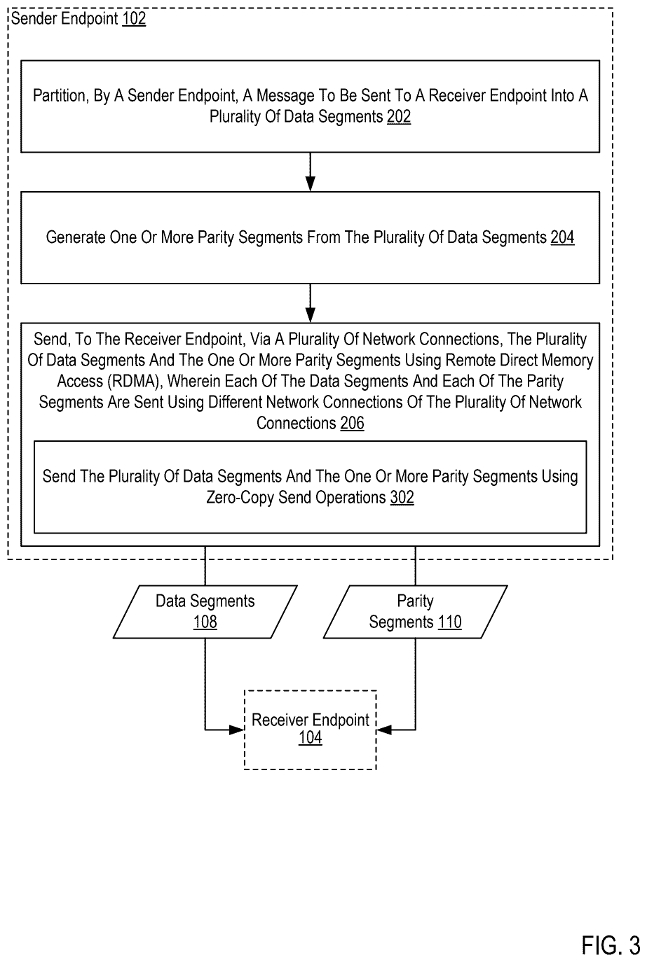

For further explanation, FIG. 3 sets forth a flowchart of another example method of erasure-coded data transfer using remote direct memory access (RDMA) in accordance with some embodiments of the present disclosure. In FIG. 3, sending 206, to the receiver endpoint 104, via a plurality of network connections 114, the plurality of data segments 108 and the one or more parity segments 110 using RDMA can include sending 302 the plurality of data segments 108 and the one or more parity segments 110 using zero-copy send operations.

As is set forth above, each RDMA write operation may include a memory address pointer indicating where the corresponding data segment 108 or parity segment 110 are stored. In some embodiments, to perform an RDMA operation, the RNIC 112a accesses the data to be sent directly from memory as identified by the memory address pointer. This allows for the data to be sent without making additional copies of the data, such as in other approaches where data to be sent is copied into a kernel, and potentially further copied, before being encoded into a frame or other datagram to be sent. Thus, overall memory usage is reduced and performance is increased due to the lack of these additional copies.

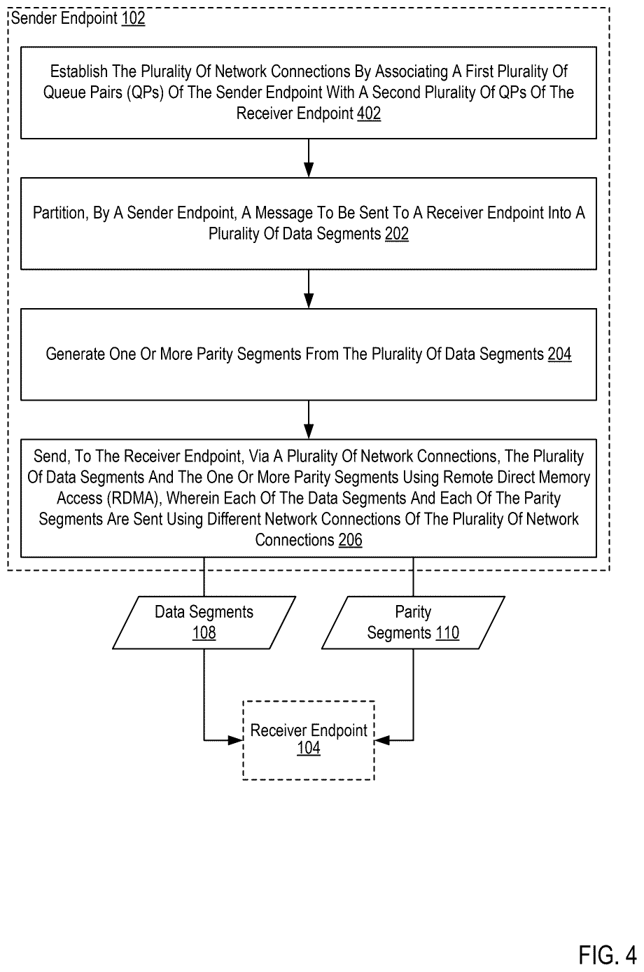

For further explanation, FIG. 4 sets forth a flowchart of another example method of erasure-coded data transfer using RDMA in accordance with some embodiments of the present disclosure. The method of FIG. 4 includes establishing 402 the plurality of network connections 114 by associating a first plurality of queue pairs (QPs) of the sender endpoint 102 with a second plurality of QPs of the receiver endpoint 104. In some embodiments, establishing 402 the plurality of network connections 114 is performed as part of a synchronization or other handshaking operation between the sender endpoint and the receiver endpoint 104. In some embodiments, establishing 402 the plurality of network connections 114 includes creating, in both the sender endpoint 102 and the receiver endpoint 104, a plurality of QPs. For example, in order to support an EC scheme using K data segments 108 and M parity segments 110 both the sender endpoint 102 and the receiver endpoint 104 may each create K+M QPs. In some embodiments, these QPs may include UC QPs that can withstand packet drops and do not perform retransmissions, allowing for control of drop recovery by libraries or applications performing the data transfer. The plurality of network connections 114 may then be established 402, for each QP of the sender endpoint 102, a network connection 114 to a corresponding QP of the receiver endpoint 104.

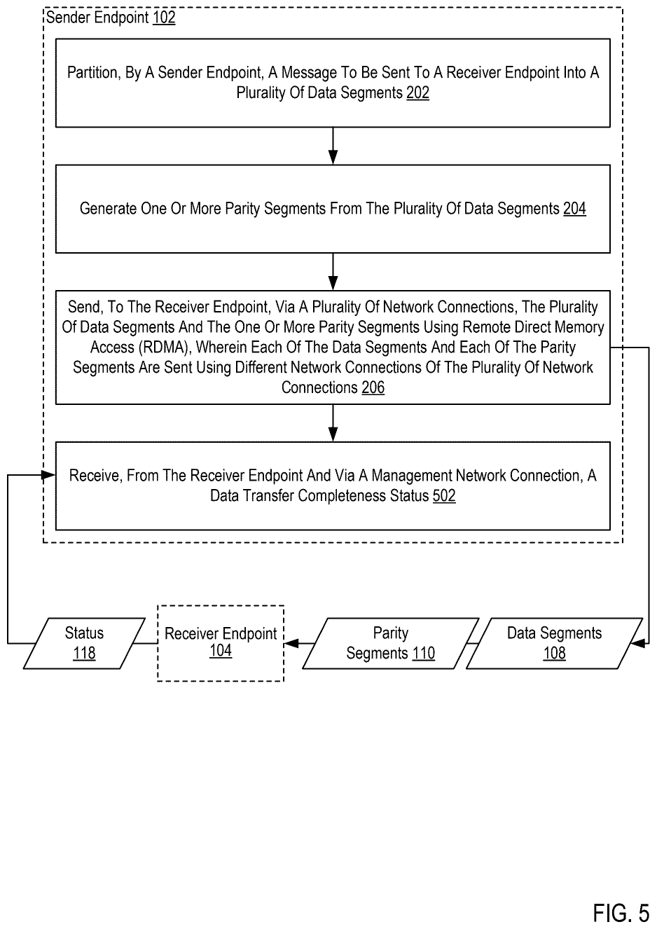

For further explanation, FIG. 5 sets forth a flowchart of another example method of erasure-coded data transfer using remote direct memory access (RDMA) in accordance with some embodiments of the present disclosure. The method of FIG. 5 includes receiving 502, from the receiver endpoint 104 and via a management network connection 116, a data transfer completeness status (e.g., a status 118). The data transfer completeness status is an indication from the receiver endpoint 104 describing whether the message 106 was successfully received. In some embodiments, the status 118 may indicate a successful data transfer where all data segments 108 were successfully received by the receiver endpoint 104 or where any lost data segments 108 were successfully reconstructed using the received parity segments 110. In some embodiments, the status 118 may indicate an unsuccessful or failed data transfer where one or more data segments 108 were lost and where these one or more data segments 108 could not be reconstructed using any parity segments 110 received by the receiver endpoint 104. For example, the status 118 may indicate a failed data transfer where the number of lost segments exceeds the number of generated parity segments 110. In other words, the status 118 may indicate a failed data transfer where the number of lost data segments 108 exceeds the number of received parity segments 110.

The status 118 may be received 502 via a management network connection 116. The management network connection 116 is another network connection between the sender endpoint 102 and the receiver endpoint 104 in addition to the network connections 114 used for transferring data segments 108 and parity segments 110. Thus, the management network connection 116 may be used for any data transfers or exchanges beyond sending data segments 108 and parity segments 110 using RDMA. In some embodiments, the management network connection 116 may be established as part of a synchronization or handshaking operation as described above. In some embodiments, the management network connection 116 may include a network connection between another pair of QPs or another type of network connection as can be appreciated.

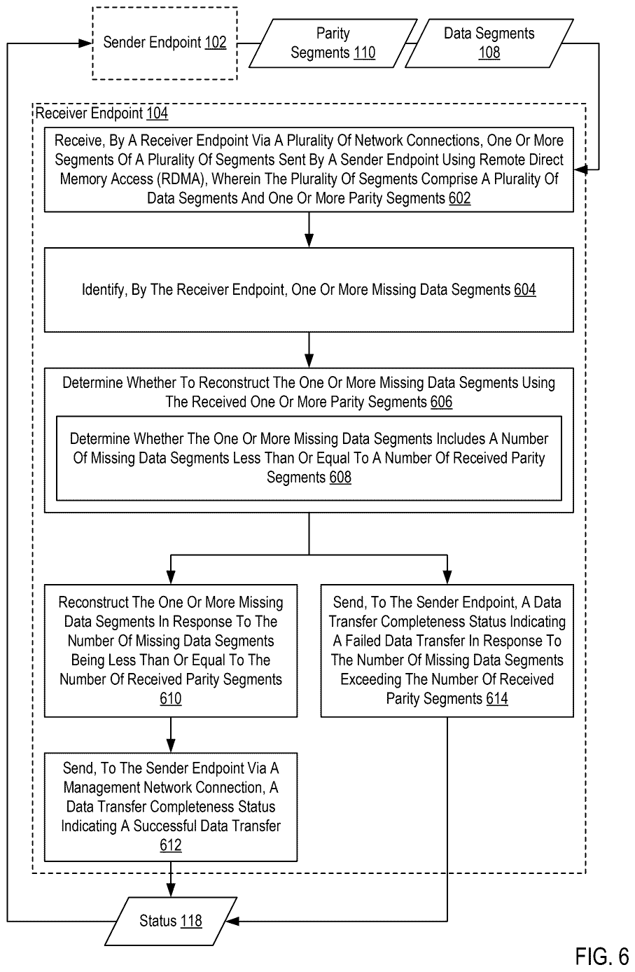

For further explanation, FIG. 6 sets forth a flowchart of another example method of erasure-coded data transfer using RDMA in accordance with some embodiments of the present disclosure. The method of FIG. 6 may be performed, for example, by a system 100 of FIG. 1. The method of FIG. 6 includes receiving 602, by a receiver endpoint 104 via a plurality of network connections 114, one or more segments of a plurality of segments sent by a sender endpoint 102 using remote direct memory access (RDMA), wherein the plurality of segments comprise a plurality of data segments 108 and one or more parity segments 110. The plurality of segments may include segments sent by the sender endpoint 102 according to similar approaches as are set forth above. For example, in some embodiments, each of the segments may be received 602 via different network connection 114 of a plurality of network connections 114. This may include receiving 602 the plurality of segments via a plurality of network connections 114 each corresponding to a different network path. In some embodiments, receiving 602 the plurality of segments may include writing any received segments into a buffer. For example, the plurality of segments may be written by an RNIC 112b into a buffer identified to the sender endpoint 102 with a token that serves to authenticate the sender endpoint 102.

The method of FIG. 6 also includes identifying 604, by the receiver endpoint 104, one or more missing data segments 108. In some embodiments, identifying 604 the one or more missing data segments 108 includes identifying any data segments 108 not received by the receiver endpoint 104 after expiration of some time limit, or based on other rules or criteria. For example, a timer may begin relative to some event associated with receiving 602 the plurality of segments. Once the time limit has been reached, any data segments 108 that have not been received may be deemed as lost.

The method of FIG. 6 also includes determining 606 (e.g., by the receiver endpoint 104) whether to reconstruct the one or more missing data segments 108 using the received one or more parity segments 110. Determining 606 whether to reconstruct the one or more missing data segments 108 using the received one or more parity segments 110 may include determining whether the one or more missing data segments 108 can be reconstructed using the received data segments 108 and parity segments 110. For example, in some embodiments, determining 606 whether to reconstruct the one or more missing data segments 108 using the received one or more parity segments 110 may include determining 608 whether the one or more missing data segments 108 includes a number of missing data segments 108 less than or equal to a number of received parity segments 110.

Where the one or more missing data segments 108 includes a number of missing data segments 108 less than or equal to a number of received parity segments 110, the one or more missing data segments 108 can be reconstructed using the received data segments 108 and parity segments 110. Accordingly, the method of FIG. 6 also includes reconstructing 610 the one or more missing data segments 108 in response to the number of missing data segments 108 being less than or equal to the number of received parity segments 110. The particular approaches and operations used in reconstructing 610 the one or more missing data segments 108 may depend on the particular EC algorithm used to generate the parity segments 110. For example, the receiver endpoint 104 may reconstruct 610 the one or more missing data segments 108 by applying a reconstruction algorithm corresponding to the EC algorithm used to generate the parity segments 110. The receiver endpoint 104 may apply this reconstruction algorithm to the received parity segments 110 and data segments 108 to reconstruct 610 the missing data segments 108.

The method of FIG. 6 also includes sending 612, to the sender endpoint 102 via a management network connection 116, a data transfer completeness status (e.g., a status 118) indicating a successful data transfer. As the missing data segments 108 were able to be reconstructed 610 using the received parity segments 110 the receiver endpoint 104 has successfully received the data contents of the message 106. In some embodiments, a library facilitating the data transfer may generate a signal to a higher-level application indicating the successful data transfer.

Where the one or more missing data segments 108 includes a number of missing data segments 108 exceeding the number of received parity segments 110, the missing data segments 108 cannot be reconstructed using the received parity segments 110. The data transfer of the message 106 may be deemed to have failed. Accordingly, the method of FIG. 6 also includes sending 614, to the sender endpoint 102, a data transfer completeness status (e.g., a status 118) indicating a failed data transfer in response to the number of missing data segments 108 exceeding the number of received parity segments 110. In some embodiments, a library facilitating the data transfer may generate a signal to a higher-level application indicating the failed data transfer.

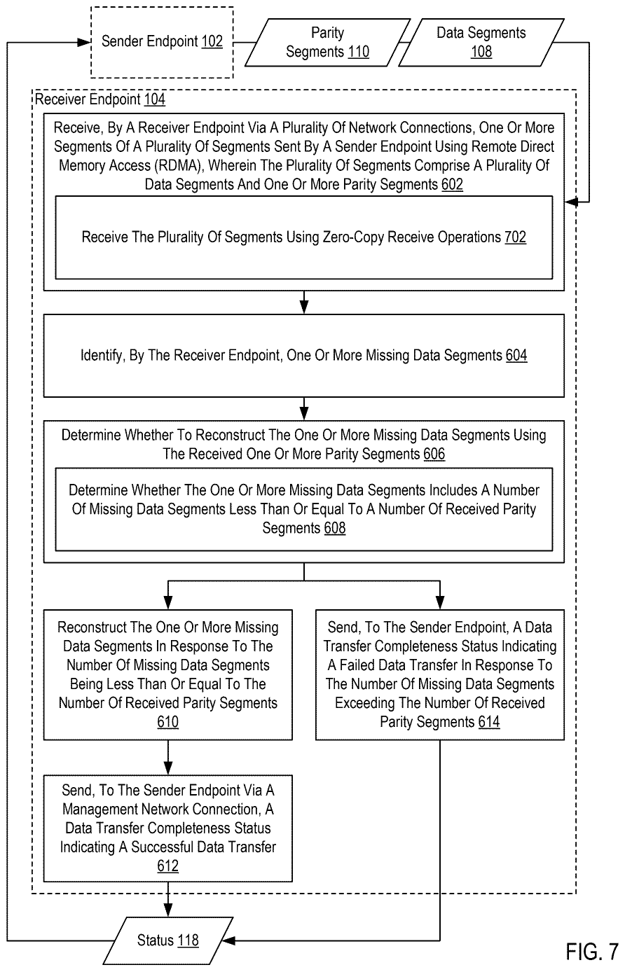

For further explanation, FIG. 7 sets forth a flowchart of another example method of erasure-coded data transfer using remote direct memory access (RDMA) in accordance with some embodiments of the present disclosure. The method of FIG. 7 is similar to FIG. 6 in that the method of FIG. 7 also includes: receiving 602, by a receiver endpoint 104 via a plurality of network connections 114, one or more segments of a plurality of segments sent by a sender endpoint 102 using remote direct memory access (RDMA), wherein the plurality of segments comprise a plurality of data segments 108 and one or more parity segments 110; identifying 604, by the receiver endpoint 104, one or more missing data segments 108; determining 606 whether to reconstruct the one or more missing data segments 108 using the received one or more parity segments 110; determining 608 whether the one or more missing data segments 108 includes a number of missing data segments 108 less than or equal to a number of received parity segments 110; and reconstructing 610 the one or more missing data segments 108 in response to the number of missing data segments 108 being less than or equal to the number of received parity segments 110; or sending 614, to the sender endpoint 102, a data transfer completeness status indicating a failed data transfer in response to the number of missing data segments 108 exceeding the number of received parity segments 110.

The method of FIG. 7 differs from FIG. 6 in that receiving 602 the plurality of segments includes receiving 702 the plurality of segments using zero-copy receive operations. This may include writing, by an RNIC 112b or another network interface, data received via an RDMA write operation directly into memory. For example, the RNIC 112b may write a received 602 segment into a buffer or other area of memory identified by the corresponding write operation. As no duplicate copies of the received segments are created, this improves overall memory usage and performance.

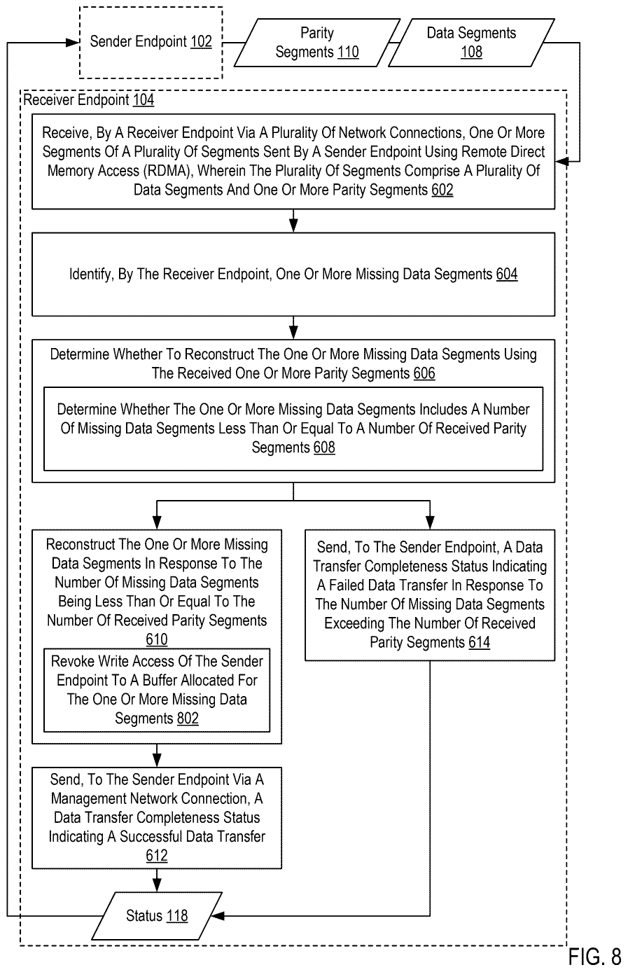

For further explanation, FIG. 8 sets forth a flowchart of another example method of erasure-coded data transfer using remote direct memory access (RDMA) in accordance with some embodiments of the present disclosure. The method of FIG. 8 is similar to FIG. 6 in that the method of FIG. 8 also includes: receiving 602, by a receiver endpoint 104 via a plurality of network connections 114, one or more segments of a plurality of segments sent by a sender endpoint 102 using remote direct memory access (RDMA), wherein the plurality of segments comprise a plurality of data segments 108 and one or more parity segments 110; identifying 604, by the receiver endpoint 104, one or more missing data segments 108; determining 606 whether to reconstruct the one or more missing data segments 108 using the received one or more parity segments 110; determining 608 whether the one or more missing data segments 108 includes a number of missing data segments 108 less than or equal to a number of received parity segments 110; and reconstructing 610 the one or more missing data segments 108 in response to the number of missing data segments 108 being less than or equal to the number of received parity segments 110; or sending 614, to the sender endpoint 102, a data transfer completeness status indicating a failed data transfer in response to the number of missing data segments 108 exceeding the number of received parity segments 110.

The method of FIG. 8 differs from FIG. 6 in that reconstructing 610 the one or more missing data segments 108 in response to the number of missing data segments 108 being less than or equal to the number of received parity segments 110 includes revoking 802 write access of the sender endpoint 102 to a buffer allocated for the one or more missing data segments 108. This may include using a Memory Window Invalidate request to revoke 802 write access to the buffer. Restricting access to this memory prevents data from being written by the sender endpoint 102 during the reconstruction process. For example, assume that some packets of missing data segment 108 were not completely lost, but only delayed due to latency. Further assume that, after determining that the data segment 108 was missing and initiating reconstruction, these delayed packets are received. Should these packets be written to the buffer, this may interfere with the reconstruction process. Accordingly, write access to this buffer may be revoked 802 to allow the missing data segment 108 to be reconstructed without interference.

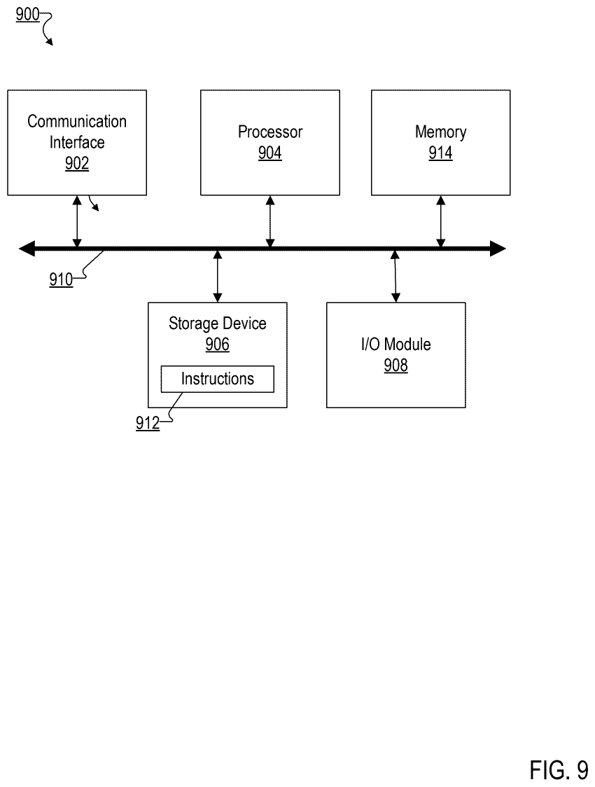

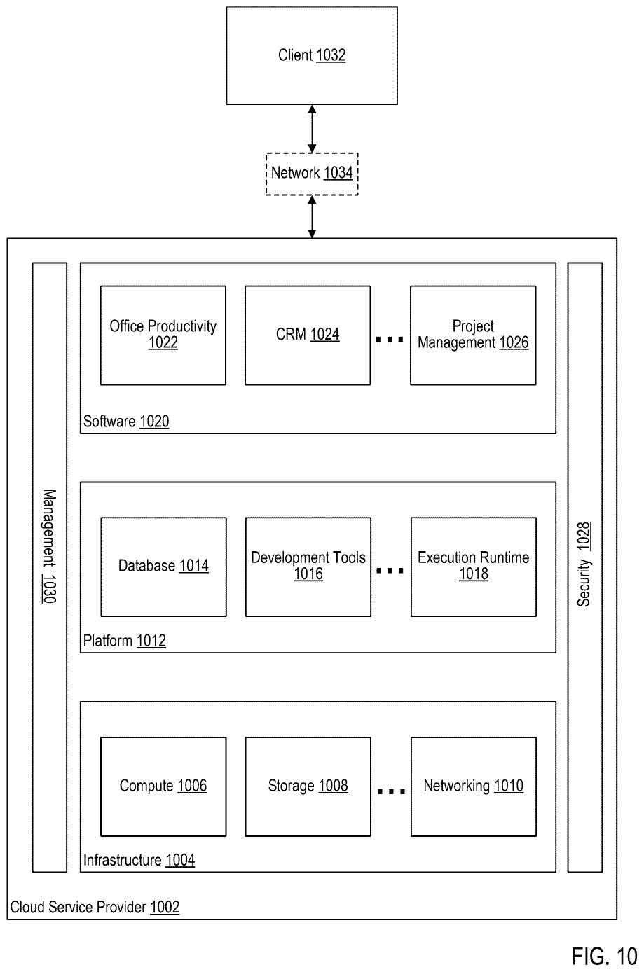

For further explanation, the sections included below provide some details regarding technologies that may be used to support erasure-coded data transfer using remote direct memory access (RDMA) in accordance with some embodiments. For example, FIG. 9 sets forth an example of a computing device that may be used in accordance with some embodiments. As an additional example of technologies that may be used to support erasure-coded data transfer using remote direct memory access (RDMA), FIG. 10 sets forth a block diagram of a cloud service provider 1002 service architecture in accordance with some embodiments of the present disclosure.

For further explanation, FIG. 9 illustrates an exemplary computing device 900 that may be specifically configured to perform one or more of the processes described herein. As shown in FIG. 9, computing device 900 may include a communication interface 902, a processor 904, a storage device 906, an input/output (I/O) module 908, and computer memory 914 communicatively connected one to another via a communication infrastructure 910. While an exemplary computing device 900 is shown in FIG. 9, the components illustrated in FIG. 9 are not intended to be limiting. Additional or alternative components may be used in other embodiments. Components of computing device 900 shown in FIG. 9 will now be described in additional detail.

Communication interface 902 may be configured to communicate with one or more computing devices. Examples of communication interface 902 include, without limitation, a wired network interface (such as a network interface card), a wireless network interface (such as a wireless network interface card), a modem, an audio/video connection, and any other suitable interface.

Processor 904 generally represents any type or form of processing unit capable of processing data and/or interpreting, executing, and/or directing execution of one or more of the instructions, processes, and/or operations described herein. Processor 904 may perform operations by executing computer-executable instructions 912 (e.g., an application, software, code, and/or other executable data instance) stored in storage device 906.

Storage device 906 may include one or more data storage media, devices, or configurations and may employ any type, form, and combination of data storage media and/or device. For example, storage device 906 may include, but is not limited to, any combination of non-volatile media and/or volatile media. Electronic data, including data described herein, may be temporarily and/or permanently stored in storage device 906. For example, data representative of computer-executable instructions 912 configured to direct processor 904 to perform any of the operations described herein may be stored within storage device 906. In some examples, data may be arranged in one or more databases residing within storage device 906.

I/O module 908 may include one or more I/O modules configured to receive user input and provide user output. I/O module 908 may include any hardware, firmware, software, or combination thereof supportive of input and output capabilities. For example, I/O module 908 may include hardware and/or software for capturing user input, including, but not limited to, a keyboard or keypad, a touchscreen component (e.g., touchscreen display), a receiver (e.g., an RF or infrared receiver), motion sensors, and/or one or more input buttons.

I/O module 908 may include one or more devices for presenting output to a user, including, but not limited to, a graphics engine, a display (e.g., a display screen), one or more output drivers (e.g., display drivers), one or more audio speakers, and one or more audio drivers. In certain embodiments, I/O module 908 is configured to provide graphical data to a display for presentation to a user. The graphical data may be representative of one or more graphical user interfaces and/or any other graphical content as may serve a particular implementation. In some examples, any of the systems, computing devices, and/or other components described herein may be implemented by computing device 900.

For further explanation and as an additional example of a supporting technology for erasure-coded data transfer using remote direct memory access (RDMA), FIG. 10 sets forth a block diagram of a cloud service provider service architecture in accordance with some embodiments. The cloud service provider 1002 can deliver a variety resources through a services-based consumption model where resources are consumed on-demand and as-a-service. Cloud service providers can provide services via cloud platforms such as, for example, Microsoft Azure™, Amazon Web Services (‘AWS’)™, Google Cloud Platform (‘GCP’)™, and others. In FIG. 10, the cloud service provider 1002 is accessed from a client device 1034 via a network 1032.

FIG. 10 depicts an embodiment where software 1020 is delivered as a service. Software-as-a-service (‘SaaS’) is a model where software applications are delivered over the internet as-a-service. Rather than installing and maintaining software locally, users can access software via a web browser or other network connected interface, eliminating the need for complex software and hardware management on the client-side. In FIG. 10, as examples of software 1020 that can be delivered as-a-service, the illustrated embodiment includes office productivity 1022 software, customer relationship management (‘CRM’) 1024 software, and project management 1026 software. The office productivity 1022 software can include applications designed to facilitate common business and personal tasks, including word processing applications, applications for spreadsheet creation, presentation design applications, and many others. The CRM 1024 software can include applications for managing a business organization's relationships and interactions with customers and potential customers. The project management 1026 software can include applications designed to help teams plan, organize, and manage projects efficiently by facilitating collaboration and tracking the progress of projects. Readers will appreciate that in other embodiments, other types of software may be delivered using a SaaS model.

FIG. 10 depicts an embodiment where platforms 1012 can be delivered as a service. Platform-as-a-service (‘PaaS’) is a model that provides cloud customers with platform resources that they can use to develop, run, and manage applications without the complexity of such deploying and managing such infrastructure on their own. In FIG. 10, as examples of platform 1012 resources that can be delivered as-a-service, the illustrated embodiment includes database 1014 services, development tools 1016 services, and execution runtime 1018 services. The database 1014 services can be used to provide access to databases without management overhead for the user as the cloud service provider manages the provisioning, scaling, and maintenance of the databases. The development tools 1016 services can provide developers with tools to design, develop, test, and deploy applications without needing to manage the underlying infrastructure. The execution runtime 1018 services can provide environments where applications or other forms of computer program code can be executed, including services to scale the execution environment. Readers will appreciate that in other embodiments, other platform resources may be delivered using a PaaS model.

FIG. 10 depicts an embodiment where infrastructure 1004 can be delivered as a service. Infrastructure-as-a-Service (‘IaaS’) is a model that provides virtualized computing resources over the internet, such that infrastructure such as servers, storage, networks, and others may be leased on demand rather than purchasing and maintaining physical hardware. In FIG. 10, as examples of infrastructure 1004 resources that can be delivered as-a-service, the illustrated embodiment includes compute 1006 services, storage 1008 services, and networking 1010 services. The compute 1006 services can be used to provide on-demand access to computational resources such as VMs, containers, and serverless functions, where the cloud service provider manages the provisioning, scaling, and maintenance of such resources. The storage 1008 services can provide storage resources that can be used to store and access data, without the need for customers to purchase and manage on-premises physical storage resources. The networking 1010 services can provide the ability to create and manage virtualized networking resources such as, for example, virtual private networks (‘VPNs’), firewalls, load balancers, and more. Readers will appreciate that in other embodiments, other infrastructure resources may be delivered using a PaaS model.

The cloud service provider of FIG. 10 also provides management 1030 resources. The management 1030 resources can include, for example, tools and interfaces that enable customers to efficiently deploy, monitor, and manage, their cloud services. Such tools can include web-based management consoles, command-line interfaces (‘CLIs’), APIs, automation tools, and other tools.

The cloud service provider of FIG. 10 also provides security 1028 resources. The security 1028 resources can include, for example, tools and services to help customers protect their cloud environments and ensure compliance with security standards. These tools and services may provide specific aspects of security, including identity and access management, network security, threat detection, compliance management, and others.

Readers will appreciate that many of the components described above may be delivered as services from a cloud service provider. For example, the virtual machines, containers, and pods described above may all be delivered via a cloud service provider. In other embodiments, other forms of compute resources may be used in place of the virtual machines or other compute resource. For example, AWS EC2 instances or other form of cloud compute instances may be utilized in place of the virtual machines.

Advantages and features of the present disclosure can be further described by the following statements:
1. A method of erasure-coded data transfer using RDMA, comprising: partitioning, by a sender endpoint, a message to be sent to a receiver endpoint into a plurality of data segments by logically subdividing the message into a number of data segments defined as a parameter of an error coding scheme; generating, by the sender endpoint, one or more parity segments from the plurality of data segments by applying the error coding scheme to the plurality of data segments; and sending, by the sender endpoint and to the receiver endpoint, via a plurality of network connections, the plurality of data segments and the one or more parity segments using remote direct memory access (RDMA), wherein each of the data segments and each of the parity segments are sent using RDMA via different network connections of the plurality of network connections.
2. The method of statement 1, wherein each of the plurality of data segments and each of the one or more parity segments are sent using different network paths.
3. The method of statements 1 or 2, wherein sending the plurality of data segments and the one or more parity segments comprises sending the plurality of data segments and the one or more parity segments using zero-copy send operations that do not duplicate the plurality of data segments or the one or more parity segments in memory of the sender endpoint.
4. The method of any combination of one or more of statements 1-3, further comprising establishing the plurality of network connections by associating a first plurality of queue pairs (QPs) of the sender endpoint with a second plurality of QPs of the receiver endpoint.
5. The method of any combination of one or more of statements 1-4, further comprising receiving, from the receiver endpoint and via a management network connection, a data transfer completeness status.
6. The method of any combination of one or more of statements 1-5, wherein the receiver endpoint is configured to reconstruct one or more missing data segments from the one or more parity segments by applying a reconstruction algorithm corresponding to the error coding scheme to any received data segments from the plurality of data segments and any received parity segments from the one or more parity segments.
7. A method of erasure-coded data transfer using RDMA, comprising: receiving, by a receiver endpoint via a plurality of network connections, one or more segments of a plurality of segments sent by a sender endpoint using remote direct memory access (RDMA), wherein the plurality of segments comprise a plurality of data segments and one or more parity segments; identifying, by the receiver endpoint, one or more missing data segments; and determining, by the receiver endpoint, whether to reconstruct the one or more missing data segments using the received one or more segments by determining whether the one or more missing data segments includes a number of missing data segments less than or equal to a number of received parity segments.
8. The method of statement 7, further comprising reconstructing the one or more missing data segments in response to the number of missing data segments being less than or equal to the number of received parity segments by applying a reconstruction algorithm to one or more received parity segments and one or more received data segments, wherein the reconstruction algorithm corresponds to an error coding scheme used to generate the one or more parity segments from the plurality of data segments by the sender endpoint.
9. The method of statements 7 or 8, further comprising sending, by the receiver endpoint and to the sender endpoint via a management network connection, a data transfer completeness status indicating a successful data transfer.
10. The method of any combination of one or more of statements 7-9, wherein reconstructing the one or more missing data segments comprises revoking write access of the sender endpoint to a buffer allocated for the one or more missing data segments.
11. The method of any combination of one or more of statements 7-10, further comprising sending, by the receiver endpoint and to the sender endpoint, a data transfer completeness status indicating a failed data transfer in response to the number of missing data segments exceeding the number of received parity segments.
12. The method of any combination of one or more of statements 7-11, wherein receiving the plurality of segments comprises receiving the plurality of segments using zero-copy receive operations that do not create duplicate copies of the plurality of segments in memory of the receiver endpoint.
13. The method of any combination of one or more of statements 7-12, wherein the one or more segments are received using different network paths.
14. The method of any combination of one or more of statements 7-13, wherein the sender endpoint is configured to generate the one or more parity segments using the plurality of data segments by applying an error coding scheme to the plurality of data segments.
15. A non-transitory computer readable storage medium storing instructions which, when executed, cause a processing device to: partition, by a sender endpoint, a message to be sent to a receiver endpoint into a plurality of data segments by logically subdividing the message into a number of data segments defined as a parameter of an error coding scheme; generate, by the sender endpoint, one or more parity segments from the plurality of data segments by applying the error coding scheme to the plurality of data segments; and send, by the sender endpoint and to the receiver endpoint, via a plurality of network connections, the plurality of data segments and the one or more parity segments using remote direct memory access (RDMA), wherein each of the data segments and each of the parity segments are sent using RDMA via different network connections of the plurality of network connections.
16. The non-transitory computer readable storage medium of statement 15, wherein, to send the plurality of data segments and the one or more parity segments, the instructions, when executed, further cause the processing device to send each of the plurality of data segments and each of the one or more parity segments using different network paths.
17. The non-transitory computer readable storage medium of statements 15 or 16, wherein, to send the plurality of data segments and the one or more parity segments, the instructions, when executed, further cause the processing device to send the plurality of data segments and the one or more parity segments using zero-copy send operations that do not duplicate the plurality of data segments or the one or more parity segments in memory of the sender endpoint.
18. The non-transitory computer readable storage medium of any combination of one or more of statements 15-17, wherein the instructions, when executed, further cause the processing device to establish the plurality of network connections by associating a first plurality of queue pairs (QPs) of the sender endpoint with a second plurality of QPs of the receiver endpoint.
19. The non-transitory computer readable storage medium of any combination of one or more of statements 15-18, wherein the instructions, when executed, further cause the processing device to receive, from the receiver endpoint and via a management network connection, a data transfer completeness status.
20. The non-transitory computer readable storage medium of any combination of one or more of statements 15-19, wherein the receiver endpoint is configured to reconstruct one or more missing data segments from the one or more parity segments by applying a reconstruction algorithm corresponding to the error coding scheme to any received data segments from the plurality of data segments and any received parity segments from the one or more parity segments.

Although some embodiments are described largely in the context of a system, method, or in some other way, readers will recognize that embodiments of the present disclosure may also take the form of a computer program product disposed upon computer readable storage media for use with any suitable processing system. Such computer readable storage media may be any storage medium for machine-readable information, including magnetic media, optical media, solid-state media, or other suitable media. Examples of such media include magnetic disks in hard drives or diskettes, compact disks for optical drives, magnetic tape, and others as will occur to those of skill in the art. Persons skilled in the art will immediately recognize that any computer system having suitable programming means will be capable of executing the steps described herein as embodied in a computer program product. Persons skilled in the art will recognize also that, although some of the embodiments described in this specification are oriented to software installed and executing on computer hardware, nevertheless, alternative embodiments implemented as firmware or as hardware are well within the scope of the present disclosure.

Readers will appreciate that some embodiments are described in which computer program instructions are executed on computer hardware such as, for example, one or more computer processors. Readers will appreciate that in other embodiments, computer program instructions may be executed on virtualized computer hardware (e.g., one or more virtual machines), in one or more containers, in one or more cloud computing instances (e.g., one or more AWS EC2 instances), in one or more serverless compute instances offered such as those offered by a cloud services provider, in one or more event-driven compute services such as those offered by a cloud services provider, or in some other execution environment.

In some examples, a non-transitory computer-readable medium storing computer-readable instructions may be provided in accordance with the principles described herein. The instructions, when executed by a processor of a computing device, may direct the processor and/or computing device to perform one or more operations, including one or more of the operations described herein. Such instructions may be stored and/or transmitted using any of a variety of known computer-readable media.

A non-transitory computer-readable medium as referred to herein may include any non-transitory storage medium that participates in providing data (e.g., instructions) that may be read and/or executed by a computing device (e.g., by a processor of a computing device). For example, a non-transitory computer-readable medium may include, but is not limited to, any combination of non-volatile storage media and/or volatile storage media. Exemplary non-volatile storage media include, but are not limited to, read-only memory, flash memory, a solid-state drive, a magnetic storage device (e.g., a hard disk, a floppy disk, magnetic tape, etc.), ferroelectric random-access memory (“RAM”), and an optical disc (e.g., a compact disc, a digital video disc, a Blu-ray disc, etc.). Exemplary volatile storage media include, but are not limited to, RAM (e.g., dynamic RAM).

One or more embodiments may be described herein with the aid of method steps illustrating the performance of specified functions and relationships thereof. The boundaries and sequence of these functional building blocks and method steps have been arbitrarily defined herein for convenience of description. Alternate boundaries and sequences can be defined so long as the specified functions and relationships are appropriately performed. Any such alternate boundaries or sequences are thus within the scope and spirit of the claims. Further, the boundaries of these functional building blocks have been arbitrarily defined for convenience of description. Alternate boundaries could be defined as long as the certain significant functions are appropriately performed. Similarly, flow diagram blocks may also have been arbitrarily defined herein to illustrate certain significant functionality.

To the extent used, the flow diagram block boundaries and sequence could have been defined otherwise and still perform the certain significant functionality. Such alternate definitions of both functional building blocks and flow diagram blocks and sequences are thus within the scope and spirit of the claims. One of average skill in the art will also recognize that the functional building blocks, and other illustrative blocks, modules and components herein, can be implemented as illustrated or by discrete components, application specific integrated circuits, processors executing appropriate software and the like or any combination thereof.

While particular combinations of various functions and features of the one or more embodiments are expressly described herein, other combinations of these features and functions are likewise possible. The present disclosure is not limited by the particular examples disclosed herein and expressly incorporates these other combinations.

What is claimed is:

1. A method of erasure-coded data transfer using remote direct memory access (RDMA), comprising:
partitioning, by a sender endpoint, a message to be sent to a receiver endpoint into a plurality of data segments by logically subdividing the message into a number of data segments defined as a parameter of an error coding scheme;
generating, by the sender endpoint, one or more parity segments from the plurality of data segments by applying the error coding scheme to the plurality of data segments; and
sending, by the sender endpoint and to the receiver endpoint, via a plurality of network connections, the plurality of data segments and the one or more parity segments using RDMA, wherein each of the data segments and each of the parity segments are sent using RDMA via different network connections of the plurality of network connections.

2. The method of claim 1, wherein each of the plurality of data segments and each of the one or more parity segments are sent using different network paths.

3. The method of claim 1, wherein sending the plurality of data segments and the one or more parity segments comprises sending the plurality of data segments and the one or more parity segments using zero-copy send operations that do not duplicate the plurality of data segments or the one or more parity segments in memory of the sender endpoint.

4. The method of claim 1, further comprising establishing the plurality of network connections by associating a first plurality of queue pairs (QPs) of the sender endpoint with a second plurality of QPs of the receiver endpoint.

5. The method of claim 1, further comprising receiving, from the receiver endpoint and via a management network connection, a data transfer completeness status.

6. The method of claim 1, wherein the receiver endpoint is configured to reconstruct one or more missing data segments from the one or more parity segments by applying a reconstruction algorithm corresponding to the error coding scheme to any received data segments from the plurality of data segments and any received parity segments from the one or more parity segments.

7. A method of erasure-coded data transfer using remote direct memory access (RDMA), comprising:
receiving, by a receiver endpoint via a plurality of network connections, one or more segments of a plurality of segments sent by a sender endpoint using RDMA, wherein the plurality of segments comprise a plurality of data segments and one or more parity segments;
identifying, by the receiver endpoint, one or more missing data segments; and
determining, by the receiver endpoint, whether to reconstruct the one or more missing data segments by determining whether the one or more missing data segments includes a number of missing data segments less than or equal to a number of received parity segments.

8. The method of claim 7, further comprising reconstructing, by the receiver endpoint, the one or more missing data segments in response to the number of missing data segments being less than or equal to the number of received parity segments by applying a reconstruction algorithm to one or more received parity segments and one or more received data segments, wherein the reconstruction algorithm corresponds to an error coding scheme used to generate the one or more parity segments from the plurality of data segments by the sender endpoint.

9. The method of claim 8, further comprising sending, by the receiver endpoint and to the sender endpoint via a management network connection, a data transfer completeness status indicating a successful data transfer.

10. The method of claim 8, wherein reconstructing the one or more missing data segments comprises revoking write access of the sender endpoint to a buffer allocated for the one or more missing data segments.

11. The method of claim 7, further comprising sending, by the receiver endpoint and to the sender endpoint, a data transfer completeness status indicating a failed data transfer in response to the number of missing data segments exceeding the number of received parity segments.

12. The method of claim 7, wherein receiving the plurality of segments comprises receiving the plurality of segments using zero-copy receive operations that do not create duplicate copies of the plurality of segments in memory of the receiver endpoint.

13. The method of claim 7, wherein the one or more segments are received using different network paths.

14. The method of claim 7, wherein the sender endpoint is configured to generate the one or more parity segments using the plurality of data segments by applying an error coding scheme to the plurality of data segments.

15. A non-transitory computer readable storage medium storing instructions which, when executed, cause a processing device to:
partition, by a sender endpoint, a message to be sent to a receiver endpoint into a plurality of data segments by logically subdividing the message into a number of data segments defined as a parameter of an error coding scheme;
generate, by the sender endpoint, one or more parity segments from the plurality of data segments by applying the error coding scheme to the plurality of data segments; and
send, by the sender endpoint and to the receiver endpoint, via a plurality of network connections, the plurality of data segments and the one or more parity segments using remote direct memory access (RDMA), wherein each of the data segments and each of the parity segments are sent using RDMA via different network connections of the plurality of network connections.

16. The non-transitory computer readable storage medium of claim 15, wherein, to send the plurality of data segments and the one or more parity segments, the instructions, when executed, further cause the processing device to send each of the plurality of data segments and each of the one or more parity segments using different network paths.

17. The non-transitory computer readable storage medium of claim 15, wherein, to send the plurality of data segments and the one or more parity segments, the instructions, when executed, further cause the processing device to send the plurality of data segments and the one or more parity segments using zero-copy send operations that do not duplicate the plurality of data segments or the one or more parity segments in memory of the sender endpoint.

18. The non-transitory computer readable storage medium of claim 15, wherein the instructions, when executed, further cause the processing device to establish the plurality of network connections by associating a first plurality of queue pairs (QPs) of the sender endpoint with a second plurality of QPs of the receiver endpoint.

19. The non-transitory computer readable storage medium of claim 15, wherein the instructions, when executed, further cause the processing device to receive, from the receiver endpoint and via a management network connection, a data transfer completeness status.

20. The non-transitory computer readable storage medium of claim 15, wherein the receiver endpoint is configured to reconstruct one or more missing data segments from the one or more parity segments by applying a reconstruction algorithm corresponding to the error coding scheme to any received data segments from the plurality of data segments and any received parity segments from the one or more parity segments.
